(19) United States
(12) Patent Application Publication
(10) Pub. No.: US 2006/0012459 A1
(43) Pub. Date: Jan. 19, 2006

(54) Sensor and method for measuring a current of charged particles

(75) Inventor: Kars-Michiel Hubert Lenssen, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V.

(21) Appl. No.: 10/516,644

(22) PCT Filed: May 21, 2003
(86) PCT No.: PCT/IB03/02263

§ 371 Date: Dec. 1, 2004

(30) Foreign Application Priority Data
Jun. 6, 2002 (EP) 02077213.3

(51) Int. Cl. H01L 43/08

(52) U.S. Cl. 338/32 R

(57) ABSTRACT

A current sensor (1) is disclosed for measuring a magnetic field (8) induced by a current of charged particles (3) having at least one magneto resistive sensor element (2;6;12;16) for enclosing the magnetic field induced by the current of charged particles, the magneto resistive sensor element being arranged perpendicularly to the current (3) during use. A method for accurately determining a current of charged particles is also disclosed making use of the current sensor (1). Further a protective switch device (30) is disclosed for protecting a user of an electrical device (31) by switching a supply current to the electric device off in case of malfunction of the electric device is also provided comprising the above current sensor (1).

The invention relates to a sensor for measuring a magnetic field induced by a current of charged particles.

The invention further relates to a method for measuring a current of charged particles using the inventive sensor.

The invention further relates to a protective switch device in which the inventive sensor and method are used.

A beam of charged particles induces a magnetic field outside the beam, which field may be measured by a current sensor for measuring a magnetic field. By measuring this field using a magnetic sensor, e.g. a sensor based on the Hall effect or a sensor based on the tunneling magnetoresistance (TMR) or a sensor based on the anisotropic magnetoresistance (AMR) effect, known from “The magneto resistive sensor”, Tech. Publ. 268, Philips Electronic Components and Materials, or a sensor based on the giant magneto resistance effect (GMR), see “Robust giant magneto resistance sensors”, K.-M. H. Lenssen, D. J. Adelerhof, H. J. Gassen, A. E. T. Kuiper, G. H. J. Somers and J. B. A. D. van Zon, Sensors&Actuators A85, 1 (2000), the current can be determined in a “non-intrusive” way.

The magnitude of the field H as a function of the distance from the center of the current I is given by:

$$H = \frac{1}{2 π r} \qquad ( 1 )$$

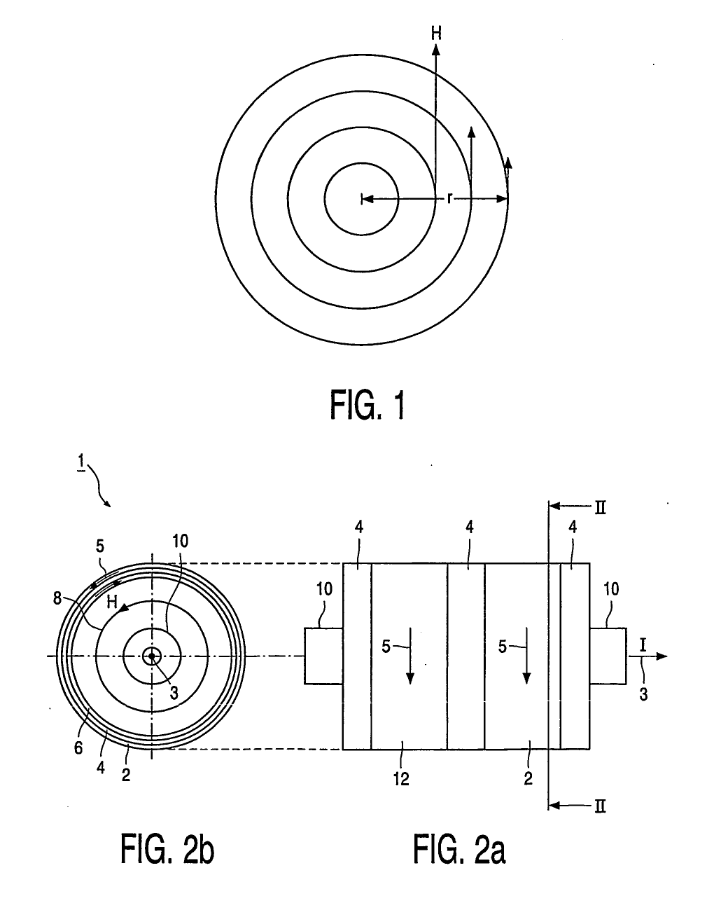

, assuming a circular cross section of the current, see FIG. 1. The sensor can be implemented by a current clamp, which is only clamped around the conductor for measurement, or can be included in a chip comprising also the current-carrying conductor. Current-sensor chips are, for example, known from U.S. Pat. No. 5,621,377, in which AMR elements on top of a conductor are used to measure the current in this conductor in a “contactiess” way.

A limitation of all present current sensors is the sensitivity to external disturbing fields. Most of these sensors rely on the measurement of the magnetic field at only one point outside the current carrying conductor. Only if the distance between sensor and current is exactly known and if there are no disturbing magnetic fields, a correct determination of the current amplitude can be made. In practice, however, there are always other magnetic fields present, like e.g. the earth magnetic field.

Current clamps indeed “average” the magnetic field over a certain line by means of a soft-magnetic yoke, but still disturbing fields entering through the non-magnetic gap in which the sensor is placed usually limit the performance. Moreover, the current-clamp geometry is less favorable for magneto resistive sensors than for Hall-sensors, since the latter is sensitive for perpendicular fields; however, the sensitivity of Hall-sensors is much lower.

One has tried to mitigate this problem by using a multitude of Hall-sensors to measure the magnetic field at several positions outside the conductor, see V. V. Serkov, “Contactless dc ammeters”, Pribory i Teldnika Éksperimenta 5, pp. 169-171, 1991. However, this configuration and the required electronics is complex and expensive, and the current measurement is still principally not correct, since theoretically one has to measure the loop integral
c∫\vec{H}·\vec{d}l=I_{enclosed}. (2)
Further, the above-mentioned problems have so far hindered the realization of a “residual-current switch” that is suitable for use in consumer electronics, e.g. hair dryers, although there is a serious demand and potentially enormous market for such a device. The sensor in such a device should be able to detect a difference of 2 or 10 mA on currents with an amplitude of up to 16 A and should contain no bulky parts, as is the case in the residual-current switches used in houses.

Therefore the invention has for its object to provide a sensor and a method for measuring currents of charged particles more accurately and being intrinsically insensitive to external disturbing magnetic fields.

To achieve the object, the sensor for measuring a magnetic field induced by a current of charged particles according to the invention comprises at least one magneto resistive sensor element for enclosing the magnetic field induced by the current of charged particles, the magneto resistive sensor element being arranged perpendicularly to the current during use.

In order to determine a current exactly, one has to measure the above-mentioned integral equation (2) along a path surrounding the current of charged particles. While this is practically impossible to achieve by most sensor types, a unique characteristic of magneto resistive sensors (TMR, AMR or GMR) can be exploited for this purpose. With a suitable configuration of the sensor elements, the magnetic field is “automatically” integrated along the sensor. The current of charged particles can be e.g. a current of electrons, holes or ions.

The resistance R of such a magneto resistance element, being for instance a strip, is given by:
R=∫ρdl=∫(ρₒ+Δρ)dl=Rₒ+∫Δρdl. (3)
Since the equation:
Δρdl∝\vec{H}·\vec{d}l=I_{enclosed}, (4)
is valid, a current sensor can be realized based on the fundamental principle of equation (2). Because the above integral along a closed loop can be determined in the sensor of the invention, insensitivity to disturbing, external fields is achieved. The directional sensitivity inherent to the magneto resistive effect automatically yields the required inproduct at least as long as the sensor is perpendicular to the plane of the current of charged particles. External fields have no influence at all on the measurement outcome, and moreover the shape of the path and the position of the current of charged particles within the loop are of no importance. An additional advantage of the sensor according to the invention is that since the integration is built-in in the sensor, additional electronic circuits can be simplified.

According to a preferred embodiment of the invention, the magneto resistive sensor element has a circular shape. This preferred embodiment has the advantage that the circumference of the circle is well defined which makes the integration along the loop easy. Moreover, manufacturing of such a circular shape is relatively easy.

The magneto resistive sensor element is therefore preferably made on a flexible substrate. This feature enables to wrap the magneto resistive sensor element around the current of charged particles in order to measure the magnetic field. The charged particles can be electrons, flowing for instance in a conductor. If the magneto resistive element encloses the magnetic field of the conductor, external fields will have no influence at all on the measurement outcome. Moreover the shape of the path and the position of the conductor or a plurality of conductors within the loop of the magneto resistive sensor element is of no importance.

According to a preferred embodiment of the invention, the magneto resistive sensor element is a strip. The resistance of such a strip of magneto resistive material is well defined, the specific resistance being p. According to equation (3) and (4) the current of charged particles can be determined. Usually a multi-layer structure of materials is used.

It is an advantage that the sensor can be made in thin film technology. This advantageous feature enables the production of very small and very light elements which can be used for domestic appliances.

Preferably, the magneto resistive sensor element has a linear resistance versus magnetic field R(H) characteristic. This enables to determine the magnetic field of the current exactly.

In order to compensate for temperature effects, preferably the sensor elements are arranged in a Wheatstone bridge configuration. The Wheatstone bridge circuit enables the temperature compensated measurement of the magnetic field.

According to a preferred embodiment of the invention, two magneto resistive sensor elements of the Wheatstone bridge configuration are present on one side of the flexible substrate and the other two magneto resistive sensor elements are present on the other side of the flexible substrate. The two magnetoresistive elements are usually a strip and are arranged parallel to each other.

During or after deposition of the multi-layer structure, the magnetization direction of a pinned layer in the multi-layer structure can be set by applying a magnetic field. The two magneto resistive elements on one side of the flexible substrate get the same magnetization direction. The flexible substrate is subsequently turned, and an identical multi-layer is deposited on the other side of the flexible substrate, getting an opposite magnetization direction.

Preferably a pair of two magneto resistive sensor elements of the Wheatstone bridge configuration has been stacked on top of the other pair of magneto resistive sensor elements, and between the two pairs an insulating material is present and a conductor is present for carrying the current of charged particles. The sensor is made in thin film technology and is therefore very suitable to be integrated on an IC. Since the current sensor can measure small currents very accurately, the sensor is very useful in for instance a magnetic memory, e.g. to accurately measure the read or write current.

To achieve the object of the invention a method for measuring a current of charged particles using the sensor as described here above, comprising the steps of:
determining a change in resistance in the sensor according to the invention caused by a magnetic field induced by the current of charged particles,
comparing the change in resistance with a reference characteristic of the sensor of the resistance versus magnetic field and determining the magnitude of the magnetic field,
calculating the magnitude of the current from the magnitude of the magnetic field.

An additional advantage of the sensor according to the invention is that since the integration is built-in in the sensor, the electronic circuit can be simplified. The known R(H) curve of the magnetoresistive sensor element can be used as a reference in a comparator circuit. A linear R(H) curve allows exact determination of the magnetic field value from the change in resistance. If the magnetorsistive sensor elements are arranged in the Wheatstone bridge configuration and the magnetoresistive sensor elements have a circular shape in the form of a strip, the enclosed current of charged particle follows from the product of the H value and the circumference of the magnetoresistive sensor elements.

For accurately measuring a residual current, the sensor with a conductor in between the two pairs of magneto resistive elements in a Wheatstone bridge configuration can be used. A current is sent through a first conductor and a current having an opposite sign is sent through a second conductor positioned parallel to the first conductor. Such a principle is useful in a residual current switch.

To achieve the object of the invention a protective switch for protecting a user of an electrical device by switching a supply current to the electric device off in case of malfunction of the electric device, comprising a sensor as described here above, and further comprising:
a comparator circuit comparing an output current or voltage of the current sensor with a reference current or voltage respectively, and
a relay device switching the supply current dependent on the output current or voltage of the comparator circuit. The protective switch device is suitable for integration in domestic appliances for example in a hairdryer, because it is small and light and has no bulky elements.

The output signal of the compare circuit can be connected to a relay which opens at least one switch and stops the current flow when the determined difference between the currents flowing in the conductors is too high.

These and various other advantages and features of novelty which characterize the present invention are pointed out with particularity in the claims annexed hereto and forming a part hereof However, for a better understanding of the invention, its advantages, and the object obtained by its use, reference should be made to the drawings which form a further part hereof, and to the accompanying descriptive matter in which there are illustrated and described preferred embodiments of the present invention.

FIG. 1 shows the magnetic field surrounding a current;

FIG. 2a shows a side view of strip-like sensor elements fabricated on a flexible substrate;

FIG. 2b shows a cross sectional view of the strip-like sensor elements along the line 11-11 in FIG. 2a;

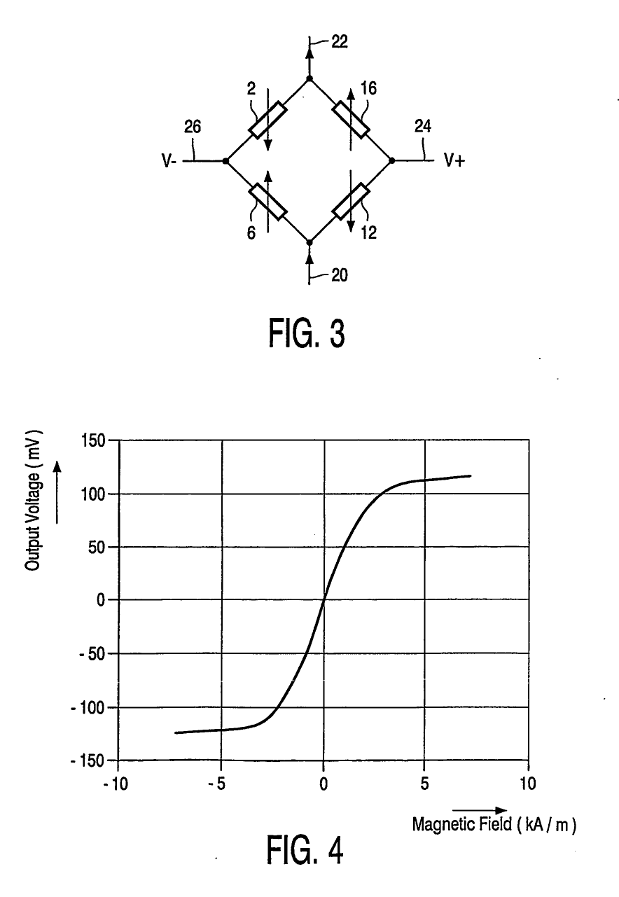

FIG. 3 shows an equivalent circuit diagram of the magneto resistive sensor elements connected in a Wheatstone bridge configuration;

FIG. 4 shows the output characteristic of the magneto resistive sensor elements connected in a Wheatstone bridge configuration;

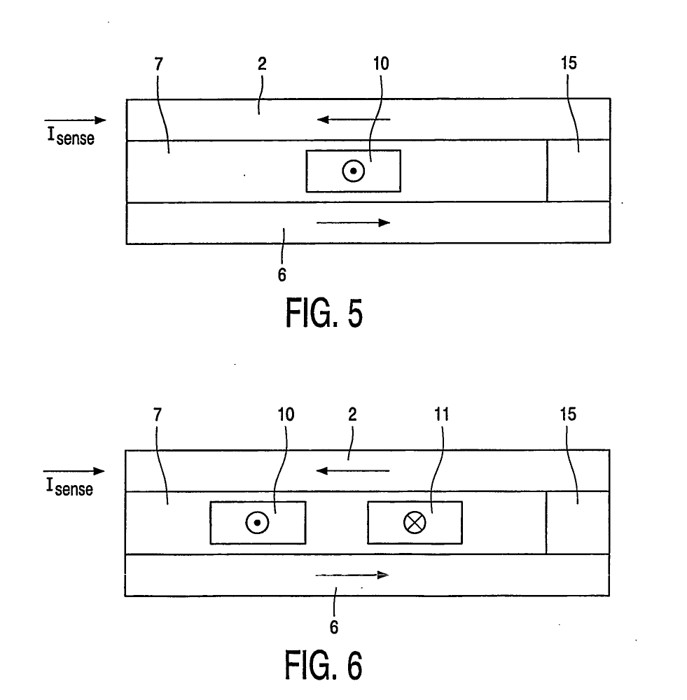

FIG. 5 shows a thin film embodiment of the magneto resistive sensor elements measuring the magnetic field of one conductor;

FIG. 6 shows a thin film embodiment of the magneto resistive sensor elements measuring the magnetic field of two conductors with opposite current directions; and

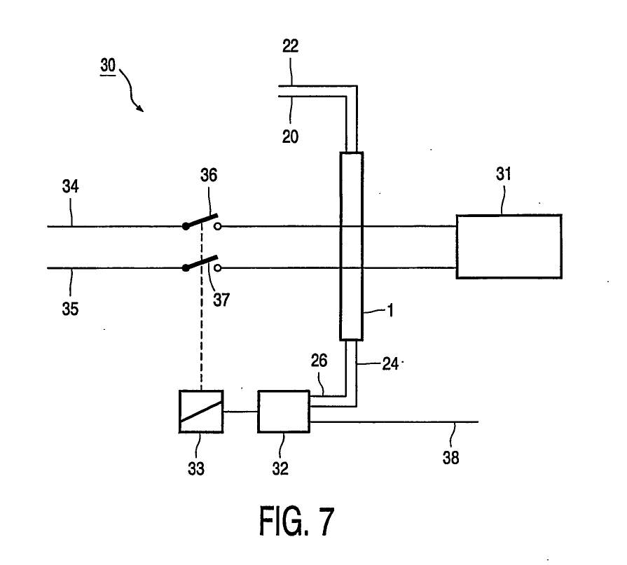

FIG. 7 shows a block diagram of a protective switch device for protecting users of electrical devices.

FIG. 1 shows a magnetic field of a current I. The amplitude of the magnetic field H decreases when the distance r to the current I flowing in a conductor is increased. The length of the arrows in FIG. 1 characterize the amplitude of the magnetic field H. The stronger the magnetic field is, the longer is the arrow. The drawn circles show the lines of equal amplitude of the magnetic field H. By measuring the magnetic field H, the current I flowing in a conductor can be determined. The magnetic field H is connected to the current I and the distance r by the equation 1.

FIG. 2a shows a side view of a magneto resistive sensor 1 and FIG. 2b shows a cross sectional view of the magneto resistive sensor 1 taken along the line II-II in FIG. 2a. In this embodiment the sensor comprises four magneto resistive elements (2,12,6,16). The side view of FIG. 2a shows the conductor 10 through which a current of charged particles 3 flows. Two magneto resistive sensor elements 2 and 12 are provided on an insulating flexible substrate 4, for instance a foil. The magneto resistive sensor elements 2, 12 are fabricated at the same time, e.g during the same sputter deposition process. The magnetization direction 5 of the magneto resistive sensor elements 2 and 12 is identical. The magneto resistive sensor elements 2,12 can be insulated from each other by an electrically insulating material, e.g silicon oxide, and can be covered with a protection layer.

The arrows drawn on the magneto resistive sensor elements 2 and 12 show the biasing direction when four magneto resistive sensor elements are connected in a Wheatstone bridge circuit configuration. The Wheatstone bridge circuit compensates the measurements from temperature influence. The arrows in FIG. 2a show the biasing directions of the magneto resistive sensor elements 2 and 12, which are arranged on top of the other two magneto resistive sensor elements 6 and 16. It is to be noted that the biasing directions of the magneto resistive sensor elements 2, 12 are opposite to the magneto resistive sensor elements 6, 16.

In the cross sectional view of FIG. 2b, the magneto resistive sensor element 2 is present on top of the insulating flexible substrate 4. On the other side of the flexible substrate 4 a strip-like sensor elements 6 is present. In depth, the magneto resistive sensor elements 12, 16 are present. The conductor 10 is located in the center of the cross sectional view. The current I flowing in the conductor 10 generates the magnetic field 8. In order to show the principle only one line of the magnetic field 8 is drawn. The magnetic field 8 is measured by the magneto resistive sensor elements 2,6,12,16. In this embodiment the magneto resistive sensor has a circular shape, but the shape of the sensor is not limited thereto and can be for example squared or rectangular.

The strip-like sensor elements 2,6,12,16 may comprise a GMR multi-layer e.g. an exchange biased spin valve with its exchange-biasing direction along the strip direction. A spin valve structure based on the GMR effect can be manufactured as follows: On a insulating substrate 4 a multi-layer structure is deposited of a buffer laag of 3.5 nm Ta/2.0 nm Py to induce the right (111) texture,
a magnetic layer having a magnetization axis 5 being the pinned layer, comprising an exchange biasing layer of 10 nm Ir₁₉Mn₈₁ and an artificial antiferromagnet of 3.5 nm Co₉₀Fe₁₀/0.8 nm Ru/3.0 nm Co₉₀Fe₁₀,
a non-magnetic spacer layer of 3 nm Cu, and
a ferromagnetic layer of 5.0 nm Py: the free layer (with below e.g. a thin layer of 1.0 nm Co₉₀Fe₁₀ which enhances the GMR effect and reduces the interlayer diffusion by which the thermal stability is increased). A protection layer of 10 nm Ta is deposited on top of the multi-layer.

Alternatively the magnetoresistive element can be a magnetic tunnel junction comprising the following multilayer-structure: a buffer layer of 3.5 nm Ta/2.0 nm NiFe, an exchange biasing layer and a pinned layer (AAF) being the magnetic layer: 15.0 nm IrMn/4.0 nm CoFe/0.8 nm Ru/4.0 nm CoFe, a non-magnetic spacer layer of 2.0 nm Al₂O₃, and a second ferromagnetic layer of e.g. 6.0 nm CoFe: the free layer.

The magnetization direction of the pinned layer of the GMR multilayer has been applied during sputter deposition in a magnetic field. The magneto resistive sensor elements 2,12 and 6,16 have been fabricated after each other in different sputter deposition processes. The magnetization direction 5 of the magneto resistive sensor elements 2,12 and 6,16 are opposite to each other. The arrows in FIG. 2b indicate the magnetization direction 5 of the pinned layer in the sensor elements 2 and 6 on both sides of the insulating flexible substrate 4.

In order to determine a current exactly, one has to measure the above-mentioned integral equation (2) along a path 8 surrounding the current conductor 10. If this can be obtained, external fields have no influence at all on the measurement outcome, and moreover the shape of the path and the position of the conductor within in the loop is of no importance.

A unique characteristic of magneto resistive sensors (TMR, AMR or GMR) can be exploited for this purpose: if a suitable configuration is chosen, the magnetic field is “automatically” integrated along the sensor.

The resistance R of such an magneto resistance strip is given by:
R=∫ρdl=∫(ρₒ+Δρ)dl=Rₒ+∫Δρdl. (3)
Since the equation:
Δρdl∝\vec{H}·\vec{d}l=I_{enclosed} (4)
is valid, a current probe can be realized based on the fundamental principle of equation (2). As this integral along a closed loop can be determined in the embodiments of the invention, insensitivity to disturbing, external fields is provided. Since the integration is built-in in the sensor, the electronics can be simplified. The directional sensitivity inherent to the magneto resistive effect automatically yields the required inproduct at least as long as the sensor is perpendicular to the plane of the conductor cross section. Moreover, all elements are now continuous, i.e. there are no gaps between the sensor parts except for a small gap for the electrical contacts.

FIG. 3 shows an equivalent circuit diagram of the magneto-resistive sensor elements connected in a Wheatstone measurement bridge arrangement. The measurement bridge comprises four magneto-resistive sensor elements 2, 12, 6, 16. The two magneto-resistive sensor elements 6 and 12 are connected to a first terminal 20 of the bridge. The first terminal 20 is the input terminal of the sense current current Iₛₑₙₛₑ. The magneto resistive sensor element 12 is connected to a second or measurement terminal 24 of the bridge. The magneto resistive sensor element 6 is connected to a third or measurement terminal 26. The magneto-resistive sensor elements 2 and 16 are connected to a forth or output terminal 22 of the bridge where the output current is present. On the other side is the magneto resistive sensor element 2 connected to the measurement terminal 26 where the measurement voltage is present. The magneto resistive element 16 is connected to the measurement terminal 24.

The voltage is measured between the terminals 24 and 26 in order to determine a voltage value characterizing the measured magnetic field H. The advantage of the Wheatstone measurement bridge is that it compensates the influence of the temperature on the measurement value. For magnetic field sensors it is often desirable to eliminate the influence of temperature variations and to realize a bipolar output by the use of a Wheatstone measurement bridge configuration. The magneto-resistive sensor elements in two of the bridge branches should have an opposite response to a magnetic field than the other two elements, as shown in FIG. 3 by the direction of the arrows. The arrows demonstrate the direction of the magnetic basing direction of the magneto-resistive sensor elements. In the case of AMR elements, the opposite response can be achieved by placing the magnetic biasing directions under −45 and +45° on the two pairs of the magneto-resistive sensor elements.

FIG. 4 shows the output voltage of the GMR-Wheatstone bridge configuration of the embodiment of FIG. 2. At a bias voltage of 5V (corresponding to a sense current of 2.5 mA and a resistance of the bridge of 2 kOhm), the sensor has a linear output characteristic for small magnetic fields over a large temperature range between 20-200° C. Small magnetic fields can be accurately measured. The GMR effect is 6%, with a small hysteresis and a very small offset voltage drift of 0.7 μV/K.

From the linear output characteristic 13 of the magnetoresistive sensor elements in the Wheatstone bridge configuration, the value of the magnetic field is determined.

For the circular shape of the magnetoresistive sensor elements, the current enclosed follows from the value of the magnetic field times 2πr.

FIG. 5 shows a thin film embodiment of the magneto-resistive sensor element measuring the magnetic field of one conductor. The sensor elements 2,12 and 6,16 are stacked on top of each other. Only two sensor elements 2,6 are shown. The sensor elements 2,12 have been separated from the sensor elements 6,16 by an electrically insulating material 7. For consumer electronics it may be desirable to have a thin film device. In this case a continuous surrounding of the conductor cannot be achieved in a practical way, but it can be approximated well by using two magneto-resistive elements.

The embodiment of FIG. 5 comprises four magneto-resistive sensor elements 2,12 and 6,16 in a Wheatstone bridge configuration, a non-magnetic wire 15, a current carrying conductor 10 and an insulating material 7. The magneto resistive sensor elements 2,6 of the halve-bridge are connected in series. The magneto resistive sensor elements 2 and 6 have opposite biasing directions and are electrically connected in series by means of a non-magnetic wire 15, e.g. a metal like Al or Cu. If the length of the magneto-resistive sensor elements 2 and 6 is significantly longer than the distance between them and if the edges are relatively far away from the conductor 10, the serial resistance of the two magneto resistive sensor elements 2 and 6 will be a very good measure for the current through the conductor. If desired, special shaped ends could be added to the elements in order to reduce the non-magneto resistive gaps.

FIG. 6 shows a thin film embodiment of the sensor measuring the magnetic field of the two conductors 10,11 with opposite current directions. The embodiment of FIG. 5 comprises four magneto-resistive sensor elements 2,12 and 6,16 in a Wheatstone bridge configuration, a non magnetic wire 15, two current carrying conductors 10 and 11 with opposite current directions and an insulating material 7. The two magneto-resistive sensor elements 2 and 6 of the halve-bridge are connected in series by the non-magnetic wire 15. The difference between the embodiment of FIG. 6 to the embodiment of FIG. 5 is that the embodiment of FIG. 6 measures the difference of the two magnetic fields of the two current carrying conductors 10 and 11. The high sensitivity of the embodiment of FIG. 6 makes it very suitable for application in a residual current switch. If the two currents with opposite directions are both enclosed by the sensor loop, the summation of their accompanying magnetic fields automatically results in a measurement of the difference between both currents. This also helps to avoid saturation of the magneto resistive embodiment. If both currents are equal, but opposite, the sensor output will be zero; if a difference arises a non-zero output will result. In contrast to inductive sensors, magneto resistive sensor elements can also be used for dc currents.

FIG. 7 shows a block diagram of a protective switch device 30 for protecting a user of an electrical device. The block diagram comprises two terminals 34 and 35 for an electric power supply. The terminal 34 is switched by a switch 36. The terminal 35 is switched by a switch 37. The two switches 36 and 37 are switched in parallel by a relay 33. The two switches 36 and 37 are connected on the other side to a load 31 being for example a motor.

Sensor 1 measures a difference of the two currents flowing to and from the load. The two terminals 20 and 22 supply a small sense current for the sensor 1. The sense current is the input current for the sensor 1 needed to measure its resistance. The output signal of the sensor 1 supplied by two terminals 24 and 26 goes to a comparator circuit 32. The comparator circuit 32 compares the output of the magneto-resistive current sensor 1 with a threshold value provided by terminal 38. In case of malfunction the current sensor 1 determines a difference between the two currents and gives an output signal to the comparator circuit 32. The comparator circuit 32 compares the output with a reference value 38. In case of malfunction, the comparator circuit 32 gives an output signal to the relay 33 in order to open the two switches 36 and 37. The block diagram of a protective switch device can be applied for instance in a hair dryer or in a circuit for detecting the on-state of head lights in cars where a missing current flow would indicate that the head light is broken.

The current sensor of the above embodiments of the invention are applicable in many different environments, for example for measuring the magnetic field of single conductors, cables, conductor paths in integrated circuits and the electric current presented by a beam of charged particles, like electrons or ions. Measuring of the magnetic field of conductors paths in integrated circuits could be integrated into on-chip testing techniques for testing, for example, current contacts.

New characteristics and advantages of the invention covered by this document have been set forth in the foregoing description. It will be understood, however, that this disclosure is, in many respects, only illustrative. Changes may be made in details, particularly in matters of shape, size, and arrangement of parts, without exceeding the scope of the invention. The scope of the invention is, of course, defined in the language in which the appended claims are expressed.

1. A sensor for measuring a magnetic field induced by a current of charged particles comprising at least one magneto resistive sensor element for enclosing the magnetic field induced by the current of charged particles, the magneto resistive sensor element being arranged perpendicularly to the current during use.

2. The sensor as claimed in claim 1, wherein the magneto resistive sensor element has a circular shape.

3. The sensor as claimed in claim 1 or 2, wherein the magneto resistive sensor element is present on a flexible substrate.

4. The sensor as claimed in claim 1, 2 or 3, wherein the magneto resistive sensor element is a strip.

5. Sensor as claimed in claim 1, wherein the magneto resistive sensor element has a linear R(H) characteristic.

6. The sensor as claimed in anyone of the claims 1 to 5, wherein magneto resistive sensor elements are arranged in a Wheatstone bridge configuration.

7. The sensor as claimed in claim 6, wherein two magneto resistive sensor elements of the Wheatstone bridge configuration are present on one side of the flexible substrate and the other two magneto resistive sensor elements are present on the other side of the flexible substrate.

8. The sensor as claimed in claim 7, wherein the two magneto resistive elements on one side of the flexible substrate have the same magnetization direction.

9. The sensor as claimed in claim 6, wherein a pair of two magneto resistive sensor elements of the Wheatstone bridge configuration has been stacked on top of the other pair of magneto resistive sensor elements, and between the two pairs an insulating material is present and a conductor is present for carrying the current of charged particles.

10. Method for measuring a current of charged particles using the sensor as claimed in anyone of the claims 1 to 9, comprising the steps of:
determining a change in resistance in the sensor according to the invention caused by a magnetic field induced by the current of charged particles,
comparing the change in resistance with a reference characteristic of the sensor of the resistance versus magnetic field and determining the magnitude of the magnetic field,
calculating the magnitude of the current from the magnitude of the magnetic field.

11. Method as claimed in claimed 10, making use of the sensor according to claim 9, wherein a current is sent through a first conductor and a current having an opposite sign is sent through a second conductor positioned parallel to the first conductor for measuring a residual current.

12. A protective switch device for protecting a user of an electrical device by switching a supply current to the electric device off in case of malfunction of the electric device, comprising a sensor as claimed in any of the claims 1 to 9, and further comprising:
a comparator circuit comparing an output current or voltage of the current sensor with a reference current or voltage respectively, and
a relay device switching the supply current dependent on the output current or voltage of the comparator circuit.
